(19) United States
(12) Patent Application Publication
(10) Pub. No.: US 2007/0218372 A1
(43) Pub. Date: Sep. 20, 2007

(54) Method For Production Of Micro-Optics Structures

(75) Inventors: Zeev Zalevsky, Rosh Ha-Ayin (IL); Vardit Eckhouse, Tel-Aviv (IL); Izhar Eyal, Bat-Yam (IL); Arkady Rudnitsky, Rehovot (IL); Nadav Cohen, Tel Aviv (IL); Yuval Kapplener, Bat Yam (IL)

Correspondence Address: BROWDY AND NEIMARK, P.L.L.C.;624 NINTH STREET, NW, SUITE 300, WASHINGTON, DC, 20001-5303, US

(73) Assignee: EXPLAY LTD., Hertzliya (IL)

(21) Appl. No.: 10/565,623

(22) PCT Filed: Jul. 25, 2004
(86) PCT No.: PCT/IL04/00678

§ 371 Date: Dec. 5, 2006

(30) Foreign Application Priority Data
Jul. 24, 2003 (US) 60490655

(51) Int. Cl. G03F 1/00; G02B 26/00

(52) U.S. Cl. 430/5

(57) ABSTRACT

A novel method for fabricating a micro-optics structure, having at least one lenslet array, is presented. A writing mask is provided being configured in accordance with an arrangement of the lenslet array to be manufactured. The writing mask is applied to a structure formed by a photosensitive layer of a predetermined thickness carried by a substrate, and the photosensitive layer is exposed through the writing mask using a predetermined spectral range of the exposure and a predetermined distance between the mask and said photosensitive layer, to thereby pattern the photosensitive layer through a diffractive optical element of said mask. The so-obtained pattern is in the form of optical nonhomogeneities in the photosensitive layer material, defining the lenslet array within the photosensitive layer.

### FIELD OF THE INVENTION

This invention is generally in the field of micro-optics techniques, and relates to a method of production of micro-optics structures, particularly for spatial light modulators.

### BACKGROUND OF THE INVENTION

Spatial light modulator (SLM) is a device that modulates either light intensity or phase of light while passing therethrough, according to the prescribed spatial pattern on the device. Spatial light modulators (SLMs) have generated interest within the applied optics community as good candidates for both adaptive optics and projection display applications. For example, SLMs may be used as miniaturized displays, typically with a screen size of less than 1.5 inches in diagonal. Light impinging the SLM is modulated to form an image and is either reflected from the SLM or goes through the SLM (depending on the type of SLM (Transmissive SLM or Reflective SLM), and exits as modulated light. SLMs are commonly used in compact data projectors, head mounted displays, in the traditional viewfinders of digital cameras and in mobile phones for Web surfing and videoconferences, etc.

The SLMs are known in the art, which use a light-valve made of a silicon chip, as the substrate material (see, for example, International Application WO 01/37033 to Wang, et al.; and an article by Hocheol Lee, et al., J. Micromech. Microeng. V. 14, P. 108-115 (2004)). Such a chip also houses the addressing electronics (at least an active matrix with integrated drivers), usually implemented in standard complementary metal oxide semiconductor (CMOS) technology which allows to obtain very reliable and stable circuits, as well as very small pixel pitches (down to 10 μm or even smaller), as well as high display resolutions.

There are known reflective and transmissive light valves. Reflective light valves bounce light off the displayed image into the viewer's lens or the projection lens. Transmissive light valves are similar to backlit, portable computer screens using LCD (Liquid Crystal Display) and EL (electro-lumination) technologies. Common reflective light valves are based on Liquid Crystal On Silicon (LCOS) and tilted micro-mirrors (DMD). Common transmissive light valves are based on Active-Matrix Liquid Crystal Displays (AMLCD).

An active surface of an SLM unit is formed by an SLM pixel arrangement that comprises a two-dimensional array of active cells (e.g., liquid crystal cells) each serving as a pixel of the image and separately operated by a modulation driver to be ON or OFF to perform the polarization rotation of light impinging thereon, thereby enabling to provide a corresponding gray level of the pixel. Some of the cells are controlled to let the light pass therethrough without a change in polarization, while others are controlled to rotate the polarization of light by certain angles, according to the input signal from the driver.

It is known that many conventional SLM units have inefficiency in light transmittance, mainly due to inactive areas in the SLM blocking significant portion of the entrance light (this is a major factor as SLMs become smaller). The ratio between the active area and the inactive area of the pixel is referred to as a fill factor or aperture ratio. In order to increase the efficiency of light transmittance the fill factor must be increased, preferably to 100%.

Various techniques have been developed to improve light focusing onto the active surface of the SLM by using a microlens array. In the prior art techniques, microlens arrays are usually externally attached to an SLM unit. As technology evolves, SLMs tend to become physically smaller due to growing applications need. However, as the pixel size becomes smaller the focal length must also be reduced in order to insure that the Bessel ring radius would not exceed the pixel size. In other words, the size of the lens must be smaller and the lens must be arranged closer to the SLM's pixel.

The SLMs usually contain an external glass layer, which mechanically supports the entire structure. In order to maintain the support for the entire structure, the thickness of the external glass layer may not be substantially reduced. This limitation prevents the micro lens array to be within a focal length of the SLMs pixel arrangement. Thus, the minimal thickness limitation of the external glass layer in conventional SLMs can result in the inability to focus the light on each pixel individually, as required.

WO 03/005733, assigned to the assignee of the present application, describes an SLM unit having the fill factor significantly increased. Such an SLM unit comprises first and second lenslet arrays formed in two polymer layers arranged at opposite sides of the pixel arrangement, such that each lens in the first array and a respective opposite lens in the second array are associated with a corresponding one of the SLM pixels.

Referring to FIG. 1A and FIG. 1B, a front view of an exemplary structure of a lenslet array 11 to be used at opposite sides of a pixel arrangement 12 in the SLM unit described in WO 03/005733 and a beam propagation scheme through the SLM unit are illustrated, schematically. The pixel arrangement (windowed structure) 12 is a two-dimensional array of spaced-apart active cells 13. Approximately 40% (varies from one SLM to another) of the total surface of the pixel arrangement structure 12 is composed of the active cell windows 13 while the rest of the surface is composed of a frame 14 that serves for thin film transistor (TFT), mechanical support and control signals of the pixel array.

As illustrated in FIG. 1B, the pixel arrangement 12 is sandwiched between a first lenslet array 11 and a second lenslet array 15. The first lenslet array 11 is a two-dimensional array of miniature lenses 110 that matches the pixel arrangement 12 of the active cells 13. Each lens 110 may, for example, have a square-like shape, and the adjacent lenses are tangent to each other, thus fills most of the surface defined by the lens array 11 (i.e., fill factor of approximately 100%).

According to this example, the first lenslet array 11 is disposed at the input side of the pixel arrangement 12 very close thereto (up to a physical contact) and the second lenslet array 15 is disposed at the output side of the pixel arrangement 12 also very close thereto, up to a physical contact. Practically, the first and second lenslet arrays can be integrated with the pixel arrangement 12 being mounted onto the opposite surfaces thereof.

Each lens 110 from the first array 11 and the respective opposite lens 150 from the second array 15 are associated with the corresponding one of the active cells 13. Each of the lenses 110 is optically designed to focus the corresponding component of the beam 16 onto a small area around its axis, at a distance of few microns behind the array. The pitch of the lenses 110 is matched to the pitch of the active cells 13, so that there is one active cell 13 centered right behind each lens, and the central point of the cell 13 is located in the back and front focal points of the respective lenslets 110 and 150, respectively. The first lenslet array 11 thus clusters the light beam 16 to correspond to the area of the arrangement 12 (active surface of the SLM unit) by splitting the light beam 16 impinging thereon into a plurality of components 17 and focusing each component by the respective lenslet to the respective pixel. The second lenslet array 15 can be substantially identical to the first lenslet array and is positioned opposite to the array 11 at the other side of the pixel arrangement 12. The second lenslet array 15 mirrors the optical effect of the first array, thus causing a reverse optical operation on the beamlets 18 emerging from the active cells 13. The second array 15 converges the individual beamlets 18 spatially modulated by the arrangement 12 to create a light beam 19.

In operation, the incoming light beam 16 is divided by the passage through the lenslet array into separate focused beamlets 17, that then pass through the cells 13 of the pixel arrangement 12, where they are modulated according to the control signal (indicative of the data to be imaged) to produce a plurality of focused beamlets 18 emerging from the pixel arrangement. The beamlets 18 pass through the lenslets 150 that create therefrom the parallel beam 19 of spatially modulated light. As a result, the fill factor of the combined arrangement (lenslet arrays and pixel arrangement) is substantially higher than that of the pixel arrangement 12 by itself.

### SUMMARY OF THE INVENTION

There is a need in the art for, and it would be useful to have, a novel method for fabrication of a micro-optics structure and a spatial light modulator (SLM) using this micro-optics structure that can comply with the growing trend of such requirements imposed on SLMs, so as to have a decreased physical size and higher pixel resolution, and to maintain a relatively great efficiency and fill factor. In order to satisfy these requirements, the micro lens array must be arranged very close to the pixel arrangement. For example, when a diameter of the lens in the lenslet array is about 12 microns, and a dimension of the active cell in the pixel arrangement is about 8 microns, for the light having the wavelength of about 0.5 microns the distance between the micro lens array and the pixel arrangement should not exceed about 160 microns, and should, preferably, be much smaller than this value. That means that the micro lens array cannot be externally attached to the SLM, and thus must be fabricated between the pixel arrangement and the glass layer as part of the entire structure, whereby the focal length can be optimized.

Furthermore, because the higher pixel density is required, there is also a need to reach a rather thin lenslet array substrate. The thickness of the lenslet array substrate should be such as to allow the light to be focused at every single pixel in the level of few microns, thus reaching a high fill factor and great improvement of the light efficiency, regardless to the SLM resolution and pixel size.

Current manufacturing technologies have difficulties in reaching thickness resolutions of up to a few microns. Thus, these technologies become less effective in ultra small sized SLMs, and are not able to provide the high fill factor and efficiency. Moreover, the light illumination may also cause an accumulation of heat over the SLM's surface. In other words, the light which impinges on the inactive surface of the SLM will generate heat, which can affect the TFTs and thus the Liquid Crystal operation.

The present invention satisfies the aforementioned need by providing a novel method for fabricating a micro-optics structure defining at least one lenslet array, in particular for use with a pixel arrangement of an SLM. The method can be employed for fabrication of special SLM components (e.g., lenslet arrays) as well as parts of multi-layered structures (e.g., an SLM arrangement together with lenslet arrays). According to an embodiment of the invention, the method includes providing a writing mask, and producing at least one lenslet array within at least one layer of the micro-optics structure by using the writing mask.

Thus, according to one aspect of the invention, there is provided a method of manufacturing a micro-optics structure having at least one lenslet array, the method comprising:

(A) providing a writing mask configured in accordance with an arrangement of the lenslet array to be manufactured; and

(B) applying said writing mask to a structure formed by a photosensitive layer carried by a substrate, and exposing the photosensitive layer through said writing mask using a predetermined spectral range of the exposure and a predetermined distance between the mask and said photosensitive layer, thereby patterning the photosensitive layer through a diffractive optical element of said mask, said pattern being in the form of optical nonhomogeneities in the photosensitive layer material, thereby producing said at least one lenslet array within said photosensitive layer.

The present invention teaches how the writing mask can be fabricated. Once the mask is fabricated, it can be used for creating any desired number of the micro-optics structures.

According to one embodiment of the invention, the writing mask is configured to operate with spatially incoherent light. According to another embodiment of the invention, the writing mask is configured to operate with spatially coherent light.

According to one aspect of the invention, the fabricating of the incoherent light writing mask includes:

creating a computerized file related to a pattern of the incoherent light writing mask, the pattern being indicative of morphology of the micro-optics structure;

plotting the file on a photo film, thereby creating an image related to the pattern;

developing and fixing the photo-film;

minifying the image by imaging it on a milimask;

coping the image from the milimask on a glass plate.

According to another aspect of the invention, the fabricating of the incoherent light writing mask includes:

creating a computerized file related to a pattern of the incoherent light writing mask, the pattern being indicative of morphology of the micro-optics structure;

providing an undeveloped glass plate coated with a chrome and a photo-resist sensitive to e-beam radiation;

drawing the pattern on the undeveloped glass plate by using e-beam technique;

developing the glass plate;

placing the glass plate into a chrome etcher; and

removing the photo-resist from the glass plate.

For the purpose of the invention, this glass plate can be used as the writing mask.

According to an embodiment of the invention, the minifying of the image includes:

providing an undeveloped milimask coated with a light sensitive emulsion;

exposing the coated milimask to a light pattern indicative of the image;

developing and fixing the milimask.

According to an embodiment of the invention, the coping of the image on the glass plate includes:

providing an undeveloped glass plate coated with a chrome and a positive photo-resist;

exposing the glass plate to UV light passing through the milimask;

developing said glass plate;

placing the glass plate into a chrome etcher; and

removing the photo-resist from the glass plate.

According to an embodiment of the invention, the exposing of the glass plate to UV light includes positioning the glass plate at a predetermined spatial location relative the milimask and on a predetermined distance from the milimask, for example, by using a mask aligner.

According to an embodiment of the invention, the fabricating of the coherent light writing mask includes:

creating a computerized file related to a pattern of the coherent light writing mask, the pattern being indicative of morphology of the micro-optics structure;

applying at least one technique selected from diamond milling, soft lithography and direct writing to a glass plate, thereby forming the pattern having protrusions and cavities on a surface of the glass plate.

The coherent light writing mask so-fabricated thereby operates as a phase mask.

According to an embodiment of the invention, the distance a between a top of the protrusions and a bottom of the cavities has to comply with the following condition:

$$a \leq \frac{λ}{2 ( {n}_{1} - {n}_{2} )} ,$$

where λ is the wavelength of the light; n₁ and n₂ are the refractive indices of the material of the glass plate and the surrounding media, respectively.

According to a further aspect of the invention, the producing of the lenslet array includes:

(a) providing a substrate;

(b) providing a uniform layer of a predetermined thickness of a photo-resist material on the substrate, for example by utilizing spin-coating technique;

(c) applying a Soft-Baking to the substrate covered with the photo-resist material at a predetermined temperature over a predetermined time period;

(d) exposing at least a portion of the substrate covered with the photo-resist material to light passing through the writing mask over a predetermined exposure time period;

(e) applying a Post-Exposure-Baking to said substrate covered with the photo-resist material at a predetermined temperature over a predetermined time period; and

(f) gradually cooling the substrate after said Post-Exposure-Baking to a predetermined temperature.

Thus, regions within the photo-resist layer subjected to more intensive UV illumination should have different physical properties than the regions subjected to less intensive UV illumination, due to the different rate of polymerization in these regions. In particular, the refraction index of the regions of these two types is different that creates optical nonhomogeneity in the structure fabricated thereby. Thus, the micro-optics structure produced thereby has a lenselet array integrated within the photo-resist layer.

According to an embodiment of the invention, the providing of the uniform layer includes spinning the covered substrate at a speed required for obtaining the uniform photo-resist layer on the substrate of a desired thickness.

According to one embodiment of the invention, the substrate is a plate made of large area glass.

According to another embodiment of the invention, the substrate is a plate made of a silicon wafer.

According to one embodiment of the invention, the light employed for illumination of the covered substrate includes spatially incoherent UV light.

According to another embodiment of the invention, the light employed for illumination of the covered substrate includes spatially coherent UV light.

According to an embodiment of the invention, the method can further include covering the substrate with a glue layer before the step of providing the layer of the photo-resist material. The photo-resist material can, for example, be SU-8 2007. The glue layer can, for example, be made of OP-4-20658.

According to another embodiment of the invention, the producing of the lenslet array further comprises:

(g) developing the covered substrate after the gradual cooling;

(h) rinsing the covered substrate after the developing; and

(i) drying the covered substrate after the rinsing.

According to still another embodiment of the invention, the producing of the lenslet array further comprises:

(j) baking the covered substrate after the drying at a temperature in the range of 150° C. to 250° C.

According to an embodiment of the invention, the rinsing is carried out in an Isopropyl-Alcohol solution.

According to an embodiment of the invention, the drying is carried out in a stream of Nitrogen.

According to a further embodiment of the invention, the method further includes covering the lenslet structure with a flattening layer composed of an optical adhesive. The optical adhesive material can, for example, be made of OP-44. This optical adhesive has a different refractive index, which is lower from the refractive index of the photosensitive material in the case where the shape of the lenses are convex, or is a higher refractive index where the shape of the lenses are concave.

The present invention satisfies the aforementioned need in the art by providing a method for fabricating a spatial light modulator (SLM) unit. The SLM unit includes a first micro-optics structure, a second micro-optics structure and an SLM pixel arrangement sandwiched therebetween. The SLM pixel arrangement includes an ITO electrode layer, a layer of a matrix drive system and a liquid crystal layer.

According to one embodiment of the invention, the first micro-optics structure includes a substrate made of a glass plate on which a lenslet array is mounted and covered with a flattening glue layer utilizing the process of the present invention. The flattening glue layer is attached to a layer of a matrix drive system (electronics layer) of the SLM pixel arrangement. Preferably, the matrix drive system is a TFT active matrix drive system.

According to one embodiment of the invention, the first micro-optics structure includes a substrate made of a silicon wafer. According to this embodiment, an electronics layer of the SLM pixel arrangement is formed from this silicon substrate layer. The substrate layer is covered with a glue layer, e.g., made of OP-4-20658. A lenslet array, fabricated from a photo-resist material, e.g., made of SU-8 2007, is formed on the glue layer. A flattening layer, e.g., made of OP-44, is arranged over the lenslet array. The structure is then glued to glass, and through a lift-off process removed from the silicon wafer together with a thin layer containing the active pixel arrangement TFTs. When utilizing this technique, the writing mask is aligned to the pixel structure by a mask aligner, and thus the lenslets are formed directly in the relevant location not requiring further alignment.

In turn, the second micro-optics structure includes a glass plate (substrate) on which a lenslet array is mounted and covered with a flattening glue layer utilizing the process of the present invention. The flattening glue layer is coated with an ITO electrode layer of the SLM pixel arrangement.

It should be noted that the micro-optics structure of the present invention may include multiple layers of lenslets arranged on the same side of the LC unit. This concept is described in co-pending application PCT/IL03/00025, assigned to the assignee of the present application.

The micro-optics structures obtained according to the method of the present invention is of durable and reliable construction, may be easily and efficiently manufactured and marketed, and may have low manufacturing cost.

There has thus been outlined, rather broadly, the more important features of the invention so that the detailed description thereof that follows hereinafter may be better understood. Additional details and advantages of the invention will be appreciated from the detailed description, or may be learned by practice of the invention.

### BRIEF DESCRIPTION OF THE DRAWINGS

In order to understand the invention and to see how it may be carried out in practice, preferred embodiments will now be described, by way of non-limiting example only, with reference to the accompanying drawings, in which:

FIG. 1A is a front view of an exemplary structure of a lenslet array to be used at opposite sides of a pixel arrangement in an SLM unit;

FIG. 1B schematically illustrates a beam propagation scheme through an SLM unit;

FIG. 2 is a flowchart diagram schematically illustrating main steps of production of micro-optics structures, according to an embodiment of the invention;

FIGS. 3A-3C illustrate a front view of several exemplary writing masks utilized with spatially incoherent light, according to the invention;

FIG. 4 illustrates a cross-sectional view of an exemplary writing mask utilized with spatially coherent light, according to the invention;

FIGS. 5A-5D illustrate a sequence of stages of the fabrication of a lenslet array, according to an embodiment of the invention;

FIG. 6 illustrates a schematic cross-section view of a micro-optics structure, according to an embodiment of the present invention;

FIG. 7 illustrates a schematic cross-section view of a micro-optics structure, according to another embodiment of the present invention; and

FIG. 8 illustrates a schematic cross-section view of an exemplary SLM unit produced from micro-optics structures shown in FIG. 6, fabricated in accordance with the present invention; and

FIG. 9 illustrates a schematic cross-section view of an exemplary SLM unit produced from micro-optics structures shown in FIG. 7, fabricated in accordance with the present invention.

### DETAILED DESCRIPTION OF SPECIFIC EMBODIMENTS

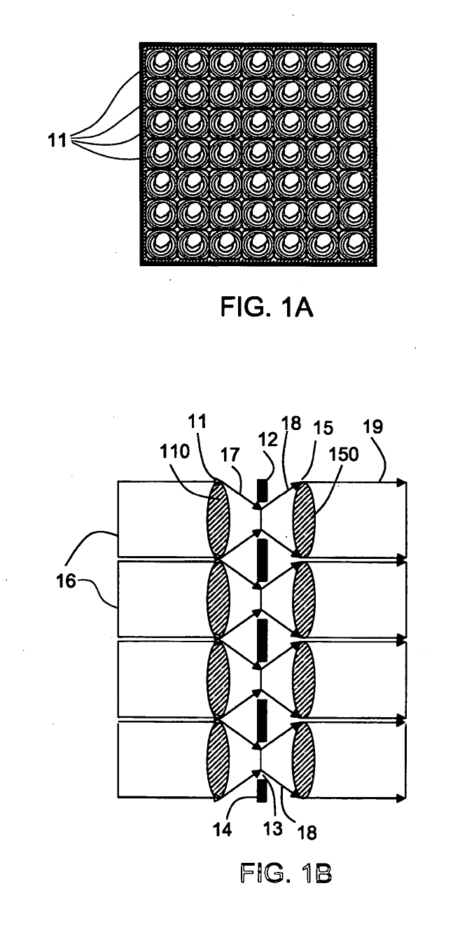

FIGS. 1A and 1B schematically illustrate an exemplary structure of a lenslet array to be used in an SLM unit, and a beam propagation scheme through such an SLM unit. The present provides a novel method for fabricating a micro-optics structure, for example such as shown in FIG. 1A.

The principles and method of production of the micro-optics structures according to the present invention as well as a spatial light modulator utilizing these micro-optics structures may be better understood with reference to the drawings and the accompanying description, wherein like reference numerals have been used throughout to designate identical elements, where it is convenient for description. It is understood that these drawings are given for illustrative purposes only and are not meant to be limiting. Dimensions of layers and regions may be exaggerated for clarity.

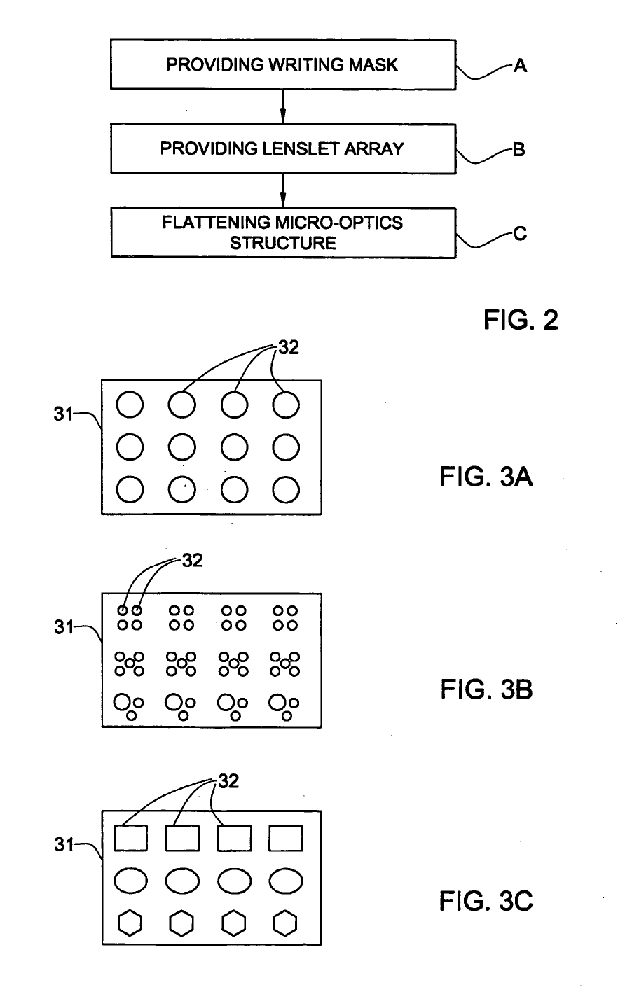

Referring to FIG. 2, general steps of production of micro-optics structures are illustrated, in accordance with an embodiment of the present invention. It should be noted that blocks in FIG. 2 are intended as functional entities only, such that the functional relationships between the entities are shown, rather than any physical connections and/or physical relationships.

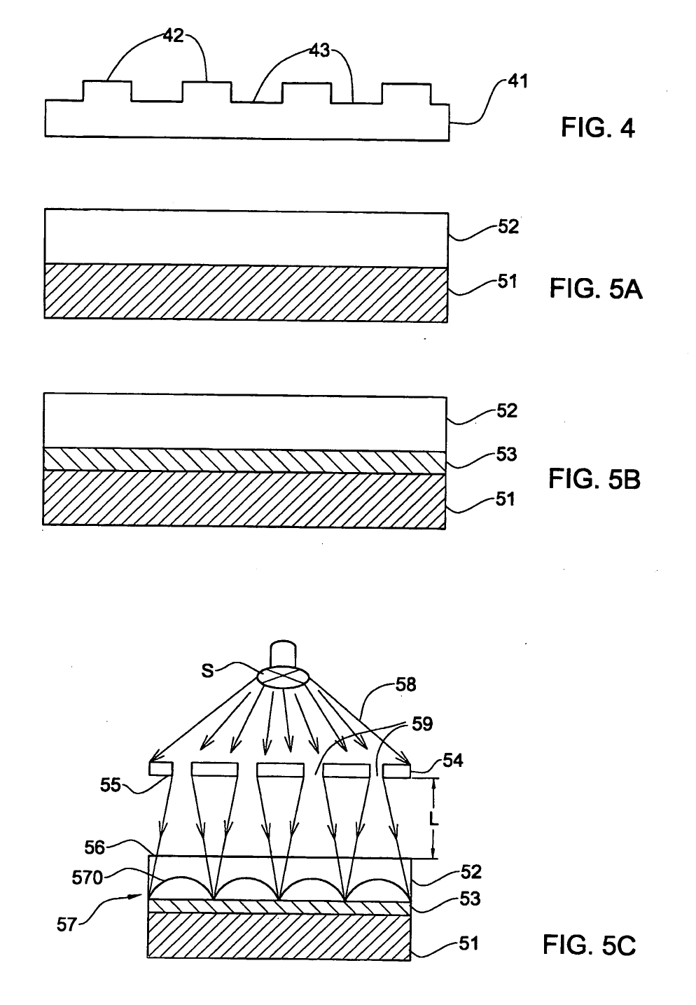

The process starts from providing of a writing mask (step A). Various examples of writing masks will be described below with reference to FIGS. 3A-3C and FIG. 4. The writing mask is then used to fabricate a lenslet array (step B). An example of the lenslet array manufacture will be described below with reference to FIGS. 5A-5D. In order to prepare a micro-optics structure appropriate for incorporation into other layers/structures, e.g., an SLM, flattening of the lenslet array is carried out (step C). It should be noted that the flattening should be such so as to preserve the focal properties between the lenslet array and the other layers/structures. This can be done by utilizing a material with different refractive index.

It should be understood that fabrication of the writing mask (step A) can be done only once. Once the mask is fabricated, it can be used for creating any desired number of the micro-optics structures. It should also be understood that the type of the writing mask that will be utilized for fabrication of lenslet arrays in the micro-optics structure of the invention depends, inter alia, on the type of light (i.e., spatially incoherent light or coherent light) employed in the fabrication process.

As will be shown herein below, the writing mask employed with spatially incoherent light illumination is composed of a substrate having opaque and transparent areas (sections). According to one example, when the writing mask is rather close to the image plane, the writing mask can shade the illumination light, to thereby create bright and shadow areas on an image plane. According to another example, the distance can be tuned as required. When the transparent areas in the mask are small (substantially not larger then 5 microns), diffraction will occur and the shadow will have different intensity levels in different areas corresponding to the desired shape of the lenslets.

Likewise, various light intensity patterns can be realized by using the writing mask that operates as a Diffractive Optics Element (DOE) placed between the coherent light source and the image plane. A DOE is a substrate on which complex microstructures are created to modulate and transform an incident wave into a predetermined pattern through diffraction. A DOE controls the diffraction of light by modifying wavefronts through the use of interference and phase control. For example, when a DOE is placed far from the light source, an incoming light can be assumed to propagate as a plane wave. As the light goes through the DOE, its properties (the phase and/or the amplitude) are changed according to the principles of optics. The modified outgoing light, which is not a plane wave anymore, produces a certain intensity pattern on the image plane in either the near field or the far field of the DOE. An example of the operating with spatially coherent light will be described below.

According to the invention, the fabrication of the writing mask includes creating a computerized file (e.g., a postscript file) related to a pattern of the writing mask to be fabricated. The pattern is indicative of morphology of the micro-optics structure to be produced using this writing mask. Depending on the type of the writing mask, various technologies and techniques can be utilized for the mask fabrication process.

According to one embodiment of the invention, the computerized file is used for fabrication an incoherent light writing mask. In such a case, the file is plotted on a photo film, thereby creating an image of the pattern. The plotting is carried out by using a high-resolution plotter/printer. An example of the plotter/printer includes, but is not limited to, a Scitex PS Dolev machine, having resolution of 3650 DPI. After the plotting, the photo-film is developed, fixed and dried in a conventional manner.

Thereafter, the image is minified by imaging it on a milimask. The minifying (e.g., 10:1) can be carried out by using a highly resolved telescopic imaging system. The minifying of the image includes providing an undeveloped milimask coated with a light sensitive material, e.g., light sensitive emulsion. The milimask can, for example, be made of a glass material. The undeveloped milimask is exposed in the imaging system to a light pattern indicative of the image. Thereafter, the milimask is developed and fixed in a conventional manner.

Then, the milimask is taken into a clean room in order to be copied on a glass plate. Preferably, the glass plate is made of a large area glass and has dimensions larger than the dimensions of the milimask. For example, when the dimensions of the milimask are about 1 cm², the glass plate can be of a square shape with the dimension of the size of about 14 cm.

In order to copy the image from the milimask on the glass plate, the glass plate is positioned at a predetermined spatial location relative to the milimask, and then illuminated with UV light passing through the milimask. The spatial location is at a predetermined distance from the milimask. When required, a mask aligner can be used. The operation of the mask aligner is known per se, and therefore will not be expounded herein. Thereafter, the glass plate is subjected to a conventional photolithographic process. Thus, the photo-resist is developed, and then the glass plate is inserted into a chrome etcher. Thereafter, the photo-resist is removed, for example, by cleaning with acetone.

As a result of the photolithographic process, the chrome is removed from those areas of the glass plate which correspond to the transparent (or at least partially transparent) areas of the milimask. Thus, these areas of the glass plate are also transparent. On the other hand, in the areas where the milimask is black, the chrome remains on the glass plate, and the corresponding areas on the glass plate are opaque after the photolithographic process. According to the invention, such a glass plate is used as the incoherent light writing mask in the method for production of micro-optics structures, as will be described below in detail.

According to another embodiment of the invention, the fabrication of the incoherent light writing mask is done by employing an e-beam lithography technique. In the beginning, a computerized file is created related to the desired pattern of the writing mask. Then, the fabrication of the incoherent light writing mask includes drawing the pattern on an undeveloped glass plate coated with chrome and a photo-resist sensitive to e-beam radiation, by applying e-beam to the undeveloped glass plate. Further, the fabrication of the writing mask includes the same steps as described above. Thus, the photo-resist is developed, and then the glass plate is inserted into chrome etcher. Thereafter, the photo-resist is removed.

It should be appreciated by a person versed in the art that, when required for the fabrication of the writing mask, the optical lithography can be combined with e-beam lithography.

FIGS. 3A-3C illustrate several examples of an incoherent light writing mask 31 fabricated as described above. These writing masks can operate as an amplitude mask. As shown in FIG. 3A, the incoherent light writing mask 31 represents an opaque glass plate having transparent areas 32 (windows) of a circular shape. It should be understood that by altering the writing mask, different types of micro-optics structures having various morphologies can be fabricated, as will be described hereinbelow. It should also be appreciated that the morphology of the micro-optics structures (for example, lens diameter of the micro lens array) depends, inter alia, on the diameter of the transparent circular areas 32 and their arrangement on the writing mask 31. For example, in order to obtain a lenslet array having lenslets of diameter of about 10 microns, the writing mask containing a structure of periodic holes with the hole diameter of approximately 1 microns and the array period of 10 microns is used.

It should be noted that, when required, the writing mask can contain clusters of transparent areas 32, where each cluster has more than one transparent circle, (see FIG. 3B). Thus, various transparent circles in such a cluster can have different diameters and generate the lens pattern by interference.

As shown in FIG. 3C, the areas 32 can also have any arbitrary shape, e.g., oval, polygonal, etc.

It should also be noted that when required, transparent areas 32 can be half-toned or gray scaled.

Referring to FIG. 4, an example of a writing mask 41 utilized with spatially coherent light is illustrated. The coherent light writing mask 41 is a patterned surface, wherein the pattern is in the form of a two-dimensional array of protrusions 42 arranged in a spaced-apart relationship with cavities 43 between them. The coherent light writing mask operates as a phase mask.

It should be appreciated that for modulation of the phase wavefront the following condition should be fulfilled:

$$\frac{2 π}{λ} ( {n}_{1} - {n}_{2} ) a \leq π$$

$$i . e . , a \leq \frac{λ}{2 ( {n}_{1} - {n}_{2} )} ,$$

where λ is the wavelength of the light, α is the distance between the top of the protrusions and the bottom of the cavities, and n₁ and n₂ are the refractive index of the material of the coherent light writing mask 41 and the surrounding media, e.g., air, respectively.

Many approaches are known in the art for fabrication of the coherent light writing mask 41. These approaches include, but are not limited to, diamond milling, soft lithography and direct writing (see, for example, Nicholas F. Borrelli, Microoptics technology, Marcel Dekker, Inc., New York, 1999; R. J. Jackman et al., “Design and Fabrication of Topologically Complex, Three-Dimensional Microstructures,” Science, 1998, V. 280, P. 2091-2098; and M. T. Gale et al. “Fabrication of continuous-relief micro-optical elements by direct laser writing in photoresist,” Opt. Eng., 1994, V. 33, P. 3556-3566).

Turning back to FIG. 2, the production of micro-optics structures includes fabrication of a lenslet array (step B) by using either an incoherent light writing mask or a coherent light writing mask. FIGS. 5A-5D illustrate main stages of a process of the fabrication of a lenslet array, according to an embodiment of the invention. It should be noted that these figures are not to scale, and are not in proportion, for the purposes of clarity.

Referring to FIG. 5A, a preparation stage of the fabrication of a lenslet array is shown, according to one example. At this stage a substrate 51 is provided. According to one example, the substrate is a plate made of a large area glass. According to another example, the substrate is a plate made of a semiconductor (e.g., silicon) wafer.

Then, the substrate 51 is covered with a layer 52 of photo-resist material. An example of the photo-resist material includes, but is not limited to SU-8 2007. SU-8 2007 is a highly transparent material for the visible light range, and thus suitable for imaging applications.

In this example, the thickness of this photo resist layer is in the range of about D/2 to 5D, where D is the diameter of the lenses in the lenslet array formed thereby. Preferably, the thickness of the photo-resist layer is about 3D/4.

In order to make this layer 52 uniform on the surface of the substrate 51, the process may include spinning the substrate at a predetermined angular velocity. For example, in order to obtain a uniform layer of SU-8 2007 with the thickness of about 10 microns, the angular velocity of about 1000 rpm (revolutions per minute) is required. It should be understood that the thickness of the layer depends on the spinning velocity and the type of the photo-resist material used in the process.

Referring to FIG. 5B, a preparation stage of the fabrication of a lenslet array is shown, according to another example. According to this example, the substrate 51 is first covered with a layer 53 of glue, and then with the layer of a photo-resist material 52 placed on top of the glue layer 53. An example of the glue suitable for the purpose of the invention includes, but is not limited to, OP4-20658. The required layer thicknesses can be calculated by anyone skilled in the art depending on the difference in the index of refraction of the lenslet material and adhesive used.

Thereafter, the substrate 51 covered with either the photo-resist layer 52 (FIG. 5A) or the glue layer 53 and the photo-resist layer 52 (FIG. 5B) is subjected to a Soft-Baking stage. At this stage, the covered substrate can, for example, be heated on a level hot plate or in a convection oven at a predetermined temperature over a predetermined time period. The values of the temperature and time period depend on the type of the photo-resist used in the process. For example, when SU-8 2007 is selected as a photo-resist material, the temperature can be in the range of 70° C. to 110° C. and, preferably, in the range of 90° C. to 100° C. The predetermined time period of said Soft-Baking for this example can be is in the range of 1 minute to 3 minutes and, preferably, about 2 minutes.

Referring to FIG. 5C, the fabrication of a lenslet array further includes exposing the substrate 51 covered with the layer 52 of the photo-resist material (or with the glue layer 53 and the photo-resist layer 52) to a light pattern indicative of the lenslet array arrangement to be obtained over a predetermined exposure time period, by passing light 58 from a light source S through an incoherent writing mask 54. For this purpose, the covered substrate 51 can be inserted into a mask-aligning machine (not shown) along with the writing mask 54 of the present invention. A distance L between a surface 55 of the writing mask 54 and a surface 56 of the photo-resist layer 52 facing the writing mask can be adjusted. The distance L determines the morphology of a lens 570 of the lenslet array 57 formed in the photo-resist layer 52. For example, when SU-8 2007 is selected as a photo-resist material, the distance can be in the range of 0 microns (physical contact) to 15 microns. In the mask-aligning machine, the covered substrate is illuminated with light 58 passing through the writing mask 54. The exposure time period depends, inter alia, on the kind and thickness of the photo-resist layer 52; type of the writing mask 54; energy and type of the light (coherent light or spatially incoherent light).

The light 58 is produced by the light source S that can, for example be accommodated in the mask-aligning machine or can be located outside and guided by suitable light guiding means to the inside of the machine. For example, when spatially incoherent light is employed for illumination of the photo-resist layer 52, UV radiation in the wavelength range of 360-370 nm having specific energy between 200 mW/cm² and 300 mW/cm² can be utilized over about 0.5-1 minutes. For example, such radiation can be generated by Dymax 5000 EC UV Light Source. When spatially coherent light is employed, an excimer laser can, for example, be used as a light source.

During the exposure, when the incoherent light writing mask 54 is used, the UV light passes through transparent areas 59 of the writing mask, and due to the light diffraction or diffraction and interference, the propagation distance L between the writing mask and the surface of the photo-resist layer 52 generates light intensity distribution having lenslet like profile.

It should be understood that when a coherent light illumination is employed, a coherent light writing mask (e.g., mask 41 of FIG. 4) is utilized for creation of the lenslet array. In this case, the required light intensity distribution having lenslet like profile is generated owing to the light diffraction on the protrusions and cavities of the coherent light writing mask.

The diameter of the lens created owing to the UV illumination depends on the distance L. By selecting the distance L and using a UV light source with predetermined parameters, such as wavelength, illumination angle and coherency depth, it is possible to control the light intensity distribution, thereby to form micro-optics structures with different morphology.

Further, in order to avoid generation of mechanical stresses within the obtained micro-optics structure and complete the polymerization processes caused by the UV illumination, an additional baking of the structure can be carried out (hereinafter referred to as Post-Exposure-Baking). Thus, after the exposure step, the substrate covered with the photo-resist can, for example, be heated on a hot plate. According to another example, a convection oven may also be used for the Post-Exposure-Baking. The temperature and time of the Post-Exposure-Baking depend on the type of the photo-resist utilized. For example, when SU-8 2007 photo-resist material is used, the Post-Exposure-Baking can be carried out in two stages. In the beginning, the temperature in the range of about 60° C. to 70° C. over the time period between 0.5 and 1.5 minutes can be applied. Then, the structure can be additionally heated at the temperatures between 90 to 100 over 0.5 and 1.5 minutes. After the Post-Exposure-Baking, the structure is gradually cooled to a predetermined temperature, e.g., the room temperature.

It should be appreciated that regions within the photo-resist layer 52 subjected to more intensive UV illumination should have different physical properties than the regions subjected to less intensive UV illumination, due to the different rate of polymerization in these regions. In particular, the refraction index of the regions of these two types is different that creates an optical nonhomogeneity in the structure. Thus, the micro-optics structure produced thereby has a lenselet array integrated within the photo-resist layer 52.

Further, when required to get the lenselet array out of the photo-resist layer, the substrate (e.g., glass plate) covered with the photo-resist can be developed. A type of a developer suitable to be used for this purpose depends on the type of the photo-resist utilized for the production of the micro-optics structure. For example, when SU-8 2007 is employed, the structure can be developed in diacetone alcohol over about 2-3 minutes.

After the development, the structure can be rinsed, for example, with Isopropyl-Alcohol. Thereafter, the structure can be dried, for example, in a stream of Nitrogen.

When required, the structure can further be hard-baked at the temperature in the range of about 150° C. to 250° C.

As a result, the so-obtained lenslet array 57 remains on the substrate 51 (see FIG. 5D). In particular, when SU-8 2007 is employed, since this is a negative photo-resist, most of the photo-resist remains in the places where it was intensively illuminated by light. In turn, at the dark places during the exposure, the photo-resist is removed at the development step, and thereby the required morphology of the convex lens is formed.

It should be appreciated that by designing various writing masks it is possible to yield different morphologies formed either within the photo-resist layer or from photo-resist positioned on the substrate (glass plate or semiconductor wafer). The invented approach is general, and may be applied not only to production of circular nano-sized lenslet arrays, but also to different nano-structures with slant features, etc., that can be used in the micro- or nano-optical industry.

As indicated above, in order to prepare a micro- or nano-optics structure appropriate for incorporation into other layers/structures, e.g., an SLM, a mechanical flattening of the lenslet array obtained after the development rinsing and drying is further required. The flattening and flattening material should be such so as to preserve the focal properties between the lenslet array and the other layers/structures. The flattening material must have refraction index different from that of the lenslet material refraction index.

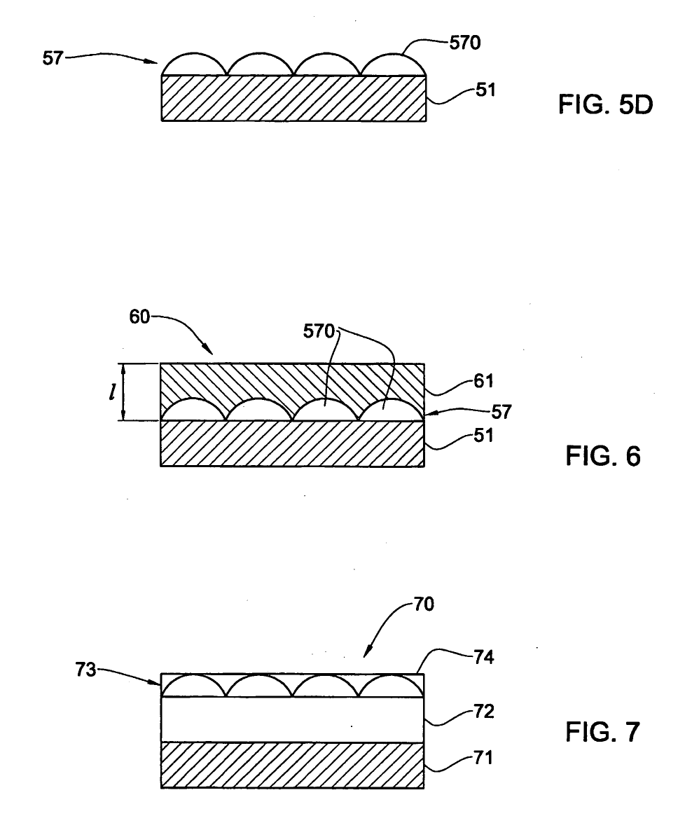

Referring to FIG. 6, a schematic cross-section view of a micro-optics structure 60 is illustrated, according to one embodiment of the present invention. The structure 60 includes the lenslet array 57 obtained on the substrate 51 (e.g., glass plate) after the development rinsing and drying and a flattening layer 61. The flattening is achieved by providing the flattening layer 61 of an optical UV glue over the lenslet array 57. This can be done by injecting an optical UV glue through a dispensing device on a top of the lenslet array 57. The dispensing device can, for example be a precision stainless steel needle, e.g., TS30-1/2. The glue used for the flattening should have such low viscosity that it would have the self-leveling property. This means that the injecting of a drop of glue and waiting several minutes, or placing the structure covered with the glue on a spinner, would lead to a situation in which the glue not only fills the gaps between the lenses 570 but also provides the uniform thin layer 61 on the top of the lenses of the lenslet array 57.

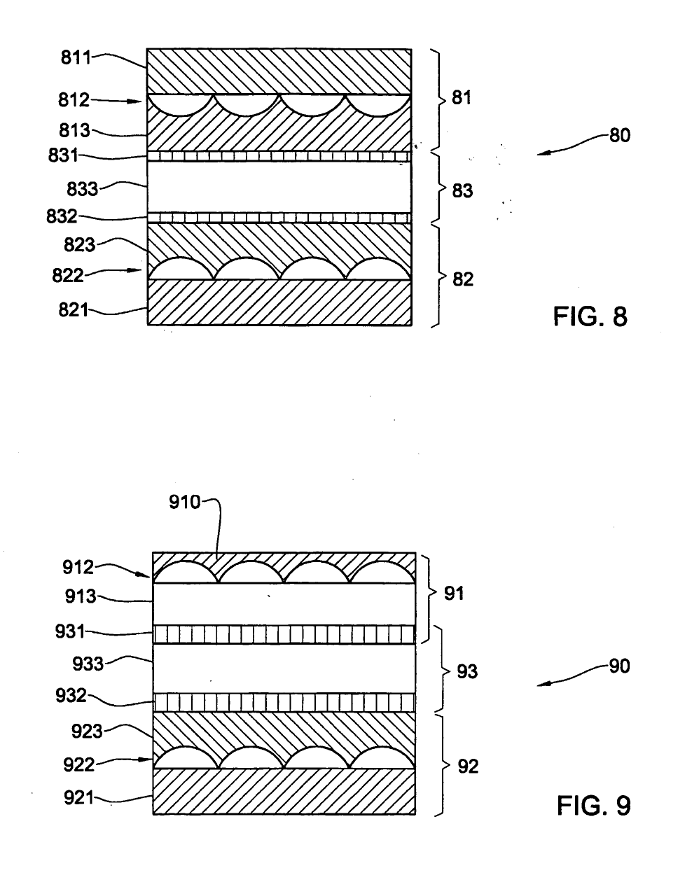

An example of the glue suitable for the purpose of the invention includes, but is not limited to, OP-44. This glue is suitable to be coated, when required, with a transparent indium-tin oxide (ITO) electrode layer (as will be described below with reference to FIG. 8) or with other layers structures (e.g., electronic structures such as transistors), thus allowing the incorporation of the lenslet array to other structures/layers (for example, to produce an SLM unit). For example, it can take approximately 10 minutes until the self-leveling property causes the glue OP-44 to form the uniform flat layer 61 on the top of the lens.

The thickness l of the flattening glue layer 61 is defined in accordance with the requirement of the focal length of the lens in the lenslet array. The thickness l (in microns) measured as a distance between the substrate 51 and the distant surface of the UV glue layer 61 can, for example, be obtained by

$$l \approx \frac{D}{2 Δ n} - 5 microns$$

where D (in microns) is the diameter of the lens of the lenslet array 57, and Δn is the difference of the refractive indexes of the lens and the glue layer materials. For example, Δn≈0.13, when the photo-resist SU-8 2007 is used for the fabrication of the lenslet array 57 and the UV glue OP 44 for the forming of the glue layer 61. Thus, according to the requirements, the thickness l of the glue layer 61 can, for example, be in the range of 20 to 100 microns.

After the fattening, the glue layer 61 is exposed to UV radiation over a predetermined time period. For example, when glue OP 44 is used for the forming of the layer 61, a Dymax 5000 EC UV Light Source can be suitable for the illumination. The predetermined time period can be in the range of about 1 to 2 minutes. Preferably, the illumination is carried out in the inert gas atmosphere, in order to prevent oxygen access to the illuminated surface.

It should be noted that one of the criteria for selecting a UV glue suitable for the purpose of fabrication of the fattening glue layer in the microstructure of the invention is that the refraction index of the glue after the illumination should be as small as possible to provide sufficient optical power to the overall structure.

FIG. 7 illustrates a schematic cross-section view of a micro-optics structure 70, according to another embodiment of the present invention. The micro-optics structure 70 includes a substrate 71 covered with a glue layer 72, e.g., made of OP-4-20658. Preferably, substrate 71 is a semiconductor (e.g., silicon) wafer. A lenslet array 73 fabricated from a photo-resist material, e.g., made of SU-8 2007, is formed on the glue layer 72, as described above with reference to FIG. 5D. The micro-optics structure 70 includes also a flattening layer 74, e.g., made of OP-44, as described above with reference to FIG. 6. It should be understood that a thickness of the glue layer 72 depends on a difference in indices of refraction of the layers. For example, for Δn=0.135 (considering SU-8 2007 and OP-44) this thickness may be in the range of 60-70 microns. Generally, this thickness is determined by the required diameter of the lens, a difference in refraction indices of layers 73 and 74, and the wavelength range of the illumination used, in order to match the focal distance of the lenslet to the distance between the lenslet and the LC material.

This embodiment distinguishes from the embodiment shown in FIG. 5B in that the glue layer 72 has a thickness substantially larger than the thickness of the glue layer 53 of FIG. 5B. This thickness can, for example, be in the range of about D/2 to 5D, where D is the diameter of the lens in the lenslet array 73. Moreover, the thickness of the flattening layer 74 is substantially smaller than the thickness of the flattening layer 61 of FIG. 6. For example, the thickness of the flattening layer 74 can be in the range of D/2 to D.

The present invention satisfies the aforementioned need in the art by providing a method for fabricating a spatial light modulator (SLM).

Thus, according to one embodiment of the invention, an SLM is built by using a structure shown in FIG. 6. As described above, this structure is produced on a glass plate and includes a lenslet array covered with a flattening layer. These glass plates serve for mechanical support of the SLM. In other words, the structure 60 (in FIG. 6) faces, by the outer surface of the glue layer 61, an active surface (pixel arrangement or LC cell) of the SLM. Hence, the lenslet array is located inside the SLM unit.

According to this embodiment, the fabricating of the SLM includes providing additional layers of the SLM. These additional layers can include, inter alia, a layer of electronics (matrix drive system), an ITO electrode layer and a liquid crystal (LC) layer.

Referring to FIG. 8, a schematic cross-section view of an exemplary SLM unit 80 produced from a micro-optics structure fabricated in accordance with one embodiment of the present invention is illustrated. The SLM unit 80 includes a first micro-optics structure 81, a second micro-optics structure 82 and an SLM pixel arrangement 83 sandwiched therebetween. The SLM pixel arrangement 83 includes an ITO electrode layer 831, a layer 832 of a matrix drive system and a liquid crystal layer 833.

The first micro-optics structure 81 includes a glass plate 811 (substrate) on which a lenslet array 812 is fabricated and covered with a flattening glue layer 813 utilizing the process of the present invention, as hereinabove described. The flattening glue layer 813 is coated with the ITO electrode layer 831 of the SLM pixel arrangement 83, thereby optically coupled thereto.

In turn, the second micro-optics structure 82 includes a glass plate 821 (substrate) on which a lenslet array 822 is fabricated and covered with a flattening glue layer 823 utilizing the process of the present invention, as hereinabove described. The flattening glue layer 823 is attached to the layer 832 of a matrix drive system of the SLM pixel arrangement 83. Preferably, the matrix drive system is a TFT active matrix drive system.

The thickness of the flattening layers 813 and 823 should be such that their thickness together with the thickness of the top layers can match the focal length of the lenses in the lenslet arrays 812 and 822. For example, if the thickness of the TFT layer and ITO is about 10 micron, and the focal length is about 50 micron, the thickness of the flattening layers should be about 40 microns.

It should be appreciated that since the micro-optics structures 81 and 82 include lenslet arrays 811 and 821, correspondingly, the efficiency of the SLM unit significantly increases, owing to the increase of the fill factor.

For example, the SLM unit 80 may be of a 100 μm thickness, wherein the pixel arrangement 83 has a thickness of 10 μm and each of the micro-optics structures 81 and 82 has a thickness of 45 μm.

According to another embodiment of the invention, the micro-optics structure shown in FIG. 7 is used for the fabrication of an SLM. According to this embodiment, an electronic layers structure is formed from the silicon substrate layer (71 in FIG. 7).

Referring to FIG. 9, a schematic cross-section view of an exemplary SLM unit 90 produced from a micro-optics structure fabricated in accordance with another embodiment of the present invention is illustrated. The SLM unit 90 includes a first micro-optics structure 91, a second micro-optics structure 92 and an SLM pixel arrangement 93 sandwiched therebetween.

The SLM pixel arrangement 93 includes an ITO electrode layer 932, a layer 931 of a matrix drive system and a liquid crystal layer 933.

According to this embodiment of the invention, the layer 931 of the matrix drive system is formed in the silicon substrate layer of the first micro-optics structure 91. In this case, the thickness of the matrix drive system in the silicon substrate layer 931 can, for example, be in the range of 1 to 10 microns. This substrate layer is covered with a glue layer 913, e.g., made of OP4-20658. A lenslet array 912 fabricated from a photo-resist material, e.g., made of SU-8 2007, is formed on the glue layer 913, as described above. A flattening layer 910, e.g., made of OP-44, covers the lenslet array 912. It should be noted that the thickness of the glue layer 913 should be such that the entire thickness of the glue layer 913 together with the thickness of the other layers arranged between the glue layer 913 and the LC layer 933 matches the focal length of the lenses of the lenslet array 912. Through a lift-off process, the matrix drive system 931 together with the micro-optics structure is lifted of from the silicon wafer to be used as one side of the liquid crystal material.

In turn, the second micro-optics structure 92 includes a glass plate 921 (substrate) on which a lenslet array 922 is fabricated and covered with a flattening glue layer 923 utilizing the process of the present invention, as hereinabove described. The flattening glue layer 923 is attached to the ITO electrode layer 932 of the SLM pixel arrangement 93.

It should be understood, although not specifically shown, that in the case the reflective SLM is manufactured using the technique of the present invention, a single structure of one or more lenslet array(s) may be used located on an input/output side of the SLM pixel arrangement, a light reflective layer (coating) being provided at the other side of the SLM pixel arrangement. Additionally, the lenslet structure may include more than one lenslet arrays at the same side of the SLM pixel arrangement. In this case, an additional lenslet structure is fabricated on top of the flattening layer. To this end, a further photosensitive material (e.g., photo-resist) is deposited on top of the flattening layer (the flattening layer therefore serving as a substrate for the second lenslet array structure) and then patterned in a manner described above.

As such, those skilled in the art to which the present invention pertains, can appreciate that while the present invention has been described in terms of preferred embodiments, the concept upon which this disclosure is based may readily be utilized as a basis for the designing of other structures, systems and processes for carrying out the several purposes of the present invention.

Also, it is to be understood that the phraseology and terminology employed herein are for the purpose of description and should not be regarded as limiting.

Finally, it should be noted that the word “comprising” as used throughout the appended claims is to be interpreted to mean “including but not limited to”.

It is important, therefore, that the scope of the invention is not construed as being limited by the illustrative embodiments set forth herein. Other variations are possible within the scope of the present invention as defined in the appended claims and their equivalents.

1. A method of manufacturing a micro-optics structure having at least one lenslet array, the method comprising:
(A) providing a writing mask configured in accordance with an arrangement of the lenslet array to be manufactured; and
(B) applying said writing mask to a structure formed by a photosensitive layer of a predetermined thickness carried by a substrate, and exposing the photosensitive layer through said writing mask using a predetermined spectral range of the exposure and a predetermined distance between the mask and said photosensitive layer, thereby patterning the photosensitive layer through a diffractive optical element of said mask, said pattern being in the form of optical nonhomogeneities in the photosensitive layer material, thereby producing said at least one lenslet array within said photosensitive layer.

2. The method of claim 1, wherein said substrate is a glass layer.

3. The method of claim 1, wherein said substrate is a semiconductor structure.

4. The method of claim 1, wherein said substrate is a layer structure of a pixel arrangement of a spatial light modulator (SLM).

5. The method of claim 3, wherein said substrate is a layer structure configured as a matrix drive system of a pixel arrangement of a spatial light modulator (SLM).

6. The method according to claim 3, wherein said photosensitive material is photoresist.

7. The method of claim 1, wherein said writing mask is configured as an incoherent light writing mask.

8. The method of claim 7, comprising fabricating said incoherent light writing mask, the fabrication including:
(i) creating a computerized file related to a pattern forming said incoherent light writing mask, the pattern being indicative of morphology of said micro-optics structure defining said at least one lenslet array;
(ii) plotting the file on a photo film, thereby creating an image related to the pattern;
(iii) developing and fixing the photo-film;
(iv) minifying the image by imaging it on a milimask;
(v) copying the image from the milimask on a glass plate, whereby said glass plate is used as said writing mask.

9. The method of claim 8, wherein said file is a postscript file.

10. The method of claim 8, wherein said milimask is made of glass material.

11. The method of claim 8, wherein said minifying of the image includes:
providing an undeveloped milimask coated with a light sensitive emulsion; exposing the coated milimask to light radiation indicative of said image; developing and fixing the milimask.

12. The method of claim 8, wherein said copying of the image on the glass plate includes:
providing an undeveloped glass plate coated with a chrome and a positive photo-resist;
exposing said glass plate to UV light passing through said milimask;
developing said glass plate; placing the glass plate into chrome etcher; and removing the photo-resist from the glass plate.

13. The method of claim 12, wherein said exposing of said glass plate to UV light includes positioning said glass plate on a predetermined distance from the milimask by using a mask aligner.

14. The method of claim 7, comprising fabricating said incoherent light writing mask, the fabrication including:
(i) creating a computerized file related to a pattern forming said incoherent light writing mask, the pattern being indicative of morphology of said micro-optics structure defining said at least one lenslet array;
(ii) providing an undeveloped glass plate coated with a chrome and a photo-resist sensitive to e-beam radiation;
(iii) drawing said pattern on the undeveloped glass plate by using e-beam technique;
(iv) developing said glass plate;
(v) placing the glass plate into chrome etcher; and
(vi) removing said photo-resist from the glass plate.

15. The method of claim 1, wherein said writing mask is a coherent light writing mask.

16. The method of claim 15, wherein said writing mask is in the form of surface relief defining an array of protrusions spaced-apart by cavities.

17. The method of claim 16, comprising fabricating said coherent light writing mask, the fabrication including:
(i) creating a computerized file related to a pattern forming said coherent light writing mask, the pattern being indicative of morphology of said micro-optics structure defining said at least one lenslet array;
(ii) applying at least one technique selected from diamond milling, soft lithography and direct writing to a glass plate, thereby forming said pattern having protrusions and cavities on a surface of the glass plate.

18. The method of claim 17, wherein for a distance α between a top of the protrusions and a bottom of the cavities the following condition is fulfilled:
$$α \leq \frac{λ}{2 ( {n}_{1} - {n}_{2} )} ,$$
where α is the wavelength of the light; n₁ and n₂ are the refractive index of the material of the glass plate and the surrounding media, respectively.

19. The method of claim 1, comprising:
(a) providing the substantially uniform layer of a predetermined thickness of the photosensitive material on the substrate;
(b) applying a Soft-Baking to said substrate covered with the photosensitive material at a predetermined temperature over predetermined time period;
(c) applying the exposure to at least a portion of the substrate covered with the photosensitive material to light passing through the writing mask over a predetermined exposure time period;
(d) applying a Post-Exposure-Baking to the substrate covered with the photosensitive material at a predetermined temperature over a predetermined time period; and
(e) gradually cooling the covered substrate after said Post-Exposure-Baking to a predetermined temperature.

20. The method of claim 19, wherein said substrate is a plate made of large area glass.

21. The method of claim 20, further comprising:
(g) developing the covered substrate after the gradual cooling:
(h) rinsing the covered substrate after the developing; and
(i) drying the covered substrate after the rinsing.

22. The method of claim 1, wherein the photosensitive material is located on top of a glue layer carried by said substrate.

23. The method of claim 19, wherein the uniform thickness of the layer of the photosensitive material is produced utilizing a spin-coating technique.

24. The method of claim 19, wherein said substrate is a semiconductor wafer.

25. The method of claim 22, wherein said substrate is a semiconductor wafer.

26. The method of claim 24, further comprising:
(g) developing the covered substrate after gradual cooling;
(h) rinsing the covered substrate after the developing; and
(i) drying the covered substrate after the rinsing.

27. The method of claim 19, further comprising:
(g) developing the covered substrate after the gradual cooling;
(h) rinsing the covered substrate after the developing; and
(i) drying the covered substrate after the rinsing.

28. The method of claim 19, wherein the photosensitive material is photoresist.

29. The method of claim 28, wherein said photo-resist material is SU-8.

30. The method of claim 19, wherein said providing of the uniform layer includes spinning the substrate at a speed required for obtaining said uniform photosensitive layer.

31. The method of claim 29, wherein said predetermined temperature of said Soft-Baking is in the range of 80° C.-100° C.

32. The method of claim 29, wherein said predetermined time period of said Soft-Baking is in the range of 1 minutes to 3 minutes.

33. The method of claim 19, wherein said light is applied to the photosensitive material at a predetermined angle.

34. The method of claim 19, wherein said light is spatially incoherent UV light.

35. The method of claim 29, wherein said light is spatially incoherent UV light characterized by specific energy between 200 mW/cm² and 30 mW/cm².

36. The method of claim 29, wherein said light is spatially incoherent UV light applied over 0.5-1 minutes.

37. The method of claim 19, wherein said light is spatially coherent UV light.

38. The method of claim 29, wherein said light is spatially coherent UV light characterized by specific energy between 200 mW/cm² and 30 mW/cm²

39. The method of claim 29, wherein said light radiation is spatially coherent UV light applied over 0.5-1 minutes.

40. The method of claim 19, wherein said Post-Exposure-Baking is carried out in more than one stage.

41. The method of claim 40, wherein said Post-Exposure-Baking is carried out in two stages.

42. The method of claim 41, wherein said predetermined temperature of said Post-Exposure-Baking at a fist stage is in the range of about 60° C. to about 70° C.

43. The method of claim 40, wherein said predetermined time period of said Post-Exposure-Baking at a fist stage is in the range of about 0.5 minutes to 1.5 minutes.

44. The method of claim 40, wherein said predetermined temperature of said Post-exposure-Baking at a second stage is in the range of about 90° C. to 100° C.

45. The method of claim 40, wherein said predetermined time period of said Post-Exposure-Baking at a second stage is in the range of about 0.5 minutes to 1.5 minutes.

46. The method of claim 19, wherein said predetermined temperature to which the substrate being gradually cooled after said Post-Exposure-Baking is a room temperature.

47. The method of claim 19, wherein said developing of the covered substrate is carried out over the time range of about 2 minutes to 3 minutes.

48. The method of claim 19, wherein said rinsing is carried out in an Isopropyl-Alcohol solution.

49. The method of claim 19, wherein said drying is carried out in a stream of Nitrogen.

50. The method of claim 22, wherein said glue layer is made of OP-4-20658.

51. The method of claim 22 comprising forming a flattening layer on top of the patterned layer of the photosensitive material.

52. The method of claims 51, wherein the flattening layer is OP-44 material.

53. The method of claim 22, comprising selecting thickness of the glue layer and the photosensitive layer so as to match a distance between the lenslet formed in the photosensitive material and a medium with witch the lenslet array is used to affect light propagation therethrough.

54. The method of claim 53, wherein said is a liquid crystal medium of an SLM.

55. A spatial Light Moulator (SLM) device manufactured by the method of claim 53.
